(19) United States
(12) Patent Application Publication
(10) Pub. No.: US 2016/0163984 A1
(43) Pub. Date: Jun. 9, 2016

(54) PRODUCTION OF A GATE ELECTRODE BY DEWETTING SILVER

(71) Applicant: SAINT-GOBAIN GLASS FRANCE, Courbevoie (FR)

(72) Inventor: Fabien LIENHART, San Diego, CA (US)

(73) Assignee: SAINT-GOBAIN GLASS FRANCE, Courbevoie (FR)

(21) Appl. No.: 14/908,427

(22) PCT Filed: Jul. 29, 2014
(86) PCT No.: PCT/FR2014/051962

§ 371 Date: Jan. 28, 2016

(30) Foreign Application Priority Data
Aug. 1, 2013 (FR) 1357665

(51) Int. Cl. H01L 51/00; H01L 51/52; H01L 51/56

(52) U.S. Cl. CPC H01L 51/0021; H01L 51/56; H01L 51/5209; H01L 2251/305; H01L 2251/558

(57) ABSTRACT

The present invention relates to a method for producing an electrode for OLEDs, comprising the following successive steps:
(a) depositing, on a transparent substrate, a metal film composed of silver or of an alloy of silver having a thickness in the range between 35 and 70 nm, preferably between 45 and 65 nm;
(b) heating the substrate covered with the metal film to a temperature in the range between 200° C. and 400° C., for a period of at least 5 minutes, preferably in the range between 20 and 60 minutes, so as to obtain the dewetting of the metal film and the formation of a random metal grid on the transparent substrate;
(c) covering the transparent substrate and the random metal grid with a continuous layer of a transparent conductive material.

The present invention relates to a method for producing an electrode in the form of a supported grid for OLEDs comprising a step of silver dewetting or agglomeration. It also relates to the electrode obtained by this method.

In the field of opto-electronic devices, and in particular OLEDs, a known technique is to increase the conductivity of electrodes made of transparent conducting oxides (TCO) by lining them with a network of metal lines that are sufficiently fine so as to be invisible to the naked eye. Such metal networks may be fabricated by complex photolithographic methods comprising several steps for masking, etching, exposure to a radiation, washing, deposition, etc.

The aim of the present invention is to provide a considerably simpler method for formation of a transparent electrode for OLEDs comprising, on a substrate made of mineral glass, a transparent conducting layer and a continuous metal network in contact with the transparent conducting layer.

The method of the present invention, in contrast to the photolithographic methods generally used for the formation of metal grids, does not require any step of masking, printing, ablation or selective etching. The key steps of the method of the present invention can be implemented on a magnetron sputtering system, which facilitates considerably the industrialization of this method of production of supported electrodes for OLEDs.

The physical phenomenon forming the basis of the present invention is the dewetting of solid thin films of silver. It is indeed known that, when certain solid metal films are heated to a temperature well below their fusion temperature, they do not remain in the form of continuous films but dewet (or agglomerate) to form metal “droplets” having a smaller contact surface area with the substrate.

The present invention takes advantage of the relatively slow dynamics of this dewetting phenomenon in order to fix the film in the process of dewetting, prior to the individualization of the metal droplets. A metal network is thus spontaneously formed which, when it is sufficiently continuous, allows the passage of an electrical current. The applicant has discovered that the conductivity and the transparency to visible light of such a “dewetted” metal network could easily be adjusted by modifying the thickness of the initial film, the temperature and the duration of heating. The geometry of the metal network formed can furthermore be adjusted by carrying out the dewetting of the silver, rather than on a perfectly smooth substrate, on a substrate comprising relief.

After formation of the random metal network by dewetting and cooling, in a known manner, a layer of a transparent conductive material is deposited uniformly covering the metal network. This transparent conductive material can be used as an anode, as a layer for adapting the work function or as a hole transport layer of the organic multilayer stack of an OLED. In any case, it will serve as a protection layer against oxidation of the silver grid whenever it might be stored and/or transported.

One subject-matter of the present invention is therefore a method for producing an electrode for OLED, comprising the following successive steps:

(a) depositing, on a transparent substrate, a metal film composed of silver or of an alloy of silver having a thickness in the range between 35 and 70 nm, preferably between 40 and 65 nm;

(b) heating the substrate covered with the metal film to a temperature in the range between 200° C. and 400° C., for a period of at least 5 minutes, preferably in the range between 15 and 90 minutes, in particular between 20 and 60 minutes, so as to obtain the dewetting of the metal film and the formation of a random metal grid on the transparent substrate;

(c) covering the transparent substrate and the random metal grid with a continuous layer of a transparent conductive material.

Another subject of the present invention is an electrode, obtainable by such a method, comprising, successively, a transparent substrate, a random grid of silver or of an alloy of silver obtained by dewetting of a metal film, and a continuous layer of a transparent conductive material covering said grid of silver or of an alloy of silver.

For the implementation of the method of the present invention, any given transparent substrate resistant to the heating in step (b) may, in principle, be used. These would of course preferably be substrates made of mineral glass, notably thin or ultra-thin glass having a thickness of less than 1 mm, but the use of polymer substrates could also be envisioned.

The substrate can be perfectly smooth, in other words having a roughness of less than a few nanometers. The dewetting of the metal film will then be governed, above all, by the surface and interface tensions of the metal.

In one embodiment, the substrate is not smooth but comprises a roughness or a relief that is sufficiently deep to orient or guide the dewetting process. Such a relief must be formed of juxtaposed individualized patterns, of regular or irregular shape, formed for example by etching or embossing.

When a metal film of silver is deposited on such a relief formed of juxtaposed individualized patterns (pyramids, mounds, islands), after dewetting the metal will preferably fill the valleys. If the valleys form a continuous network, the metal network obtained should have a good electrical conductivity while at the same time exhibiting a ratio of open area guaranteeing a good transparency of the electrode.

The film of silver or of an alloy of silver may be deposited according to any known process allowing its thickness to be controlled. By way of example of such processes, deposition by vacuum evaporation, deposition by magnetron sputtering and deposition by chemical silver plating (reduction of a silver salt) may be mentioned. It is particularly advantageous to deposit the silver film by magnetron sputtering because this technique also allows the deposition of a conductive transparent oxide the method thus being able to be implemented on the same magnetron sputtering system.

In a preferred embodiment of the method of the invention, the deposition of the metal film (step (a)) and the deposition of the transparent conductive oxide (step (c)) are therefore both implemented by physical vapor deposition (PVD), preferably by magnetron sputtering, on the same magnetron sputtering system.

It is essential to control the quantity of silver deposited per unit of surface area, in other words the thickness of the film of silver. Indeed, when this film is not thick enough, the dewetting will lead to the formation of separate metal droplets which do not form an electrically-conductive network.

In contrast, when the quantity of silver deposited is too thick, the electrical conductivity of the metal network formed is satisfactory, but the openings will be too small or too few and the grid formed will have an insufficient transmission.

A film of silver with a thickness in the range between 35 and 70 nm, preferably between 40 and 65 nm, therefore corresponds to a compromise between too high a resistivity and too low a transmission.

The step (b) for heating of the substrate carrying the film of silver is preferably implemented very shortly after the end of the step (a) in order to avoid the oxidation of the silver. In a particularly preferred embodiment, the heating of the substrate covered with silver is carried out under vacuum, on the magnetron sputtering system, between step (a) and step (c). The heating temperatures indicated hereinbefore are understood to mean the temperatures of the substrate carrying the metal film. In a radiative heating oven, the temperature of the heating elements is of course considerably higher than the temperature of the substrate, typically higher by 200° C. to 300° C. than the temperature to which it is desired to heat the substrate.

The random metal grid formed after dewetting naturally has a greater thickness than the film of silver initially deposited. This thickness is however generally less than around 150 nm.

The transparent electrically-conductive material deposited at the step (c) may be a transparent conductive oxide (TCO). When it is deposited in a sufficient amount, for example of 1 to 3 g/m², it acts both as planarization layer for the metal grid obtained by dewetting and as anode in the final OLED. The amount of transparent conductive oxide deposited must be sufficient to completely cover the grid.

The deposition of the TCO is preferably carried out by magnetron sputtering using a ceramic target. Reactive sputtering from a metal target is to be avoided because the oxygen would risk oxidizing the silver grid.

The transparent conductive material may also be formed from an organic polymer, such as a PEDOT:PSS polymer which has the same function as a TCO. Such an organic polymer offers the advantage of being able to be deposited in the liquid phase and of planarizing the metal grid perfectly.

Finally, the transparent conductive material may be the first layer, in other words the hole transport layer (or HTL) of the organic multilayer of the OLED.

The method of the present invention preferably comprises, after step (c), a second annealing step (d) at a temperature in the range between 150 and 350° C. for a period of 5 and 60 minutes.

This second annealing step essentially has the function of increasing the crystallinity and the conductivity of the TCO, which is partially amorphous after deposition.

The layer of TCO deposited on the relief created by the metal grid generally exhibits a high surface roughness, incompatible with the deposition of the stack of organic layers which require a perfectly plane surface, otherwise leakage currents due to short-circuits could be created in the final OLED.

It is therefore preferable for the layer of TCO to undergo, before or after annealing, a step of polishing the layer of transparent conductive oxide.

### EXAMPLE

### Influence of the Thickness of the Film of Silver on the Properties of the Grid Formed after Dewetting

Films of silver of various thicknesses are deposited by magnetron sputtering on a substrate made of mineral glass. The substrates carrying the films are immediately subjected to an annealing in a radiative heating oven. The temperature of the substrate is 300° C. and the heating time is 30 and 45 minutes.

The table below shows the sheet resistance (R□) and transmission of silver films of various thicknesses, dewetted by heating to a temperature of 300° C. for a period of 30 and 45 minutes.

| | | | | | After 45 | |
|---|---|---|---|---|---|---|
| | | | | | minutes of | |
| Thickness | | | After 30 minutes of | | annealing at | |
| of the Ag | Before annealing | | annealing at 300° C. | | 300° C. | |
| film | R□ (Ω/□) | T (%) | R□ (Ω/□) | T (%) | R□ (Ω/□) | T (%) |
| 30 nm | 1.58 | 23 | infinite | 50 | infinite | 46 |
| 40 nm | 0.89 | 9 | infinite | 47 | 11.16 | 40 |
| 50 nm | 0.61 | 4 | 2.62 | 41 | 1.18 | 29 |
| 60 nm | 0.51 | 2 | 0.99 | 36 | 0.62 | 24 |

These values show that it is impossible to form a continuous metal network by dewetting of a silver film of 30 nm thickness.

The dewetting of a film of 40 nm thickness leads to an electrically conductive network after 45 minutes of annealing. The absence of conductivity of the sample obtained after 30 minutes of annealing is probably due to a lack of reproducibility. In this series of tests, the optimum thickness of the film is 50 nm. The two samples obtained after 30 and 45 minutes of annealing have a sheet resistance of less than 3Ω/□ and exhibit a transmission in the range of between 29 and 41%. When the thickness of the silver film increases further, a decrease in the sheet resistance accompanied by a decrease in the transmission is observed.

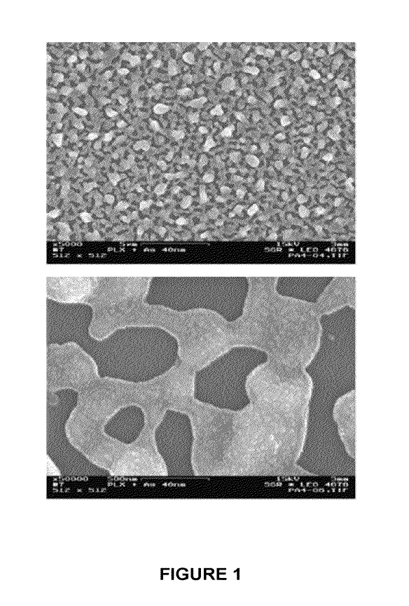

FIG. 1 shows two electron micrographs of a silver grid obtained by dewetting (30 minutes at 300° C.) of a film of silver having a thickness of 40 nm.

1: A method for producing an electrode for OLEDs, comprising the following successive steps:
(a) on a transparent substrate, depositing a metal film composed of silver or of an alloy of silver having a thickness in the range between 35 and 70 nm, preferably between 40 and 65 nm;
(b) heating the substrate covered with the metal film to a temperature in the range between 200° C. and 400° C., for a period of at least 5 minutes, preferably in the range between 20 and 60 minutes, so as to obtain the dewetting of the metal film and the formation of a random metal grid on the transparent substrate;
(c) covering the transparent substrate and the random metal grid with a continuous layer of a transparent conductive material.

2: The method as claimed in claim 1, characterized in that the transparent conductive material is a transparent conductive oxide.

3: The method of claim 1, characterized in that it further comprises, after step (c), a second annealing step (d) at a temperature in the range of between 150 and 350° C. for a period of 5 and 60 minutes.

4: The method of claim 1, characterized in that it further comprises a step (e) of polishing the layer of transparent conductive oxide.

5: The method of claim 1, characterized in that the deposition of the metal film at step (a) and the deposition of the transparent conductive oxide at step (c) are implemented by physical vapor deposition (PVD), preferably by magnetron sputtering.

6: The method of claim 1, characterized in that steps (a), (b) and (c) are implemented on the same magnetron sputtering system.

7: An electrode obtainable by a method of claim 1 comprising, successively:
a transparent substrate,
an irregular grid of silver or of an alloy of silver obtained by dewetting of a metal film, and
a continuous layer of a transparent conductive material covering said grid of silver or of an alloy of silver.
